(19) United States
(12) Patent Application Publication
(10) Pub. No.: US 2022/0080835 A1
(43) Pub. Date: Mar. 17, 2022

(54) REPLACEABLE SOLAR MODULE FOR AUTOMOTIVE USE

(71) Applicant: Utica Leaseco, LLC, Rochester Hills, MI (US)

(72) Inventors: James Gordon NEFF, Felton, CA (US); Todd KRAJEWSKI, Mountain View, CA (US)

(21) Appl. No.: 17/476,023

(22) Filed: Sep. 15, 2021

Related U.S. Application Data
(60) Provisional application No. 63/079,595, filed on Sep. 17, 2020.

(51) Int. Cl. B60L 8/00; B60L 53/80; B60R 11/00

(52) U.S. Cl. CPC B60L 8/003; B60L 53/80; B60R 2011/0047; B60R 2011/0019; B60R 11/00

(57) ABSTRACT

Removable solar panels from corresponding body parts (removable or fixed) of a vehicle may allow removal and replacement of the panels without removing and replacing the corresponding body parts. In an example, a removable photovoltaic panel for a vehicle may include an array of photovoltaic devices interconnected and assembled together, the array of photovoltaic devices may have a form factor of a surface of a corresponding body panel of the vehicle. The removable photovoltaic panel may also include an attachment layer configured to attach the array of photovoltaic devices to the surface of the corresponding body panel.

### CROSS-REFERENCE TO RELATED APPLICATION(S)

This application claims the benefit of U.S. Provisional Application No. 63/079,595, entitled “Replaceable Solar Module for Automotive Use” and filed on Sep. 17, 2020, which is expressly incorporated by reference herein in its entirety.

### BACKGROUND

### Technical Field

The present disclosure relates generally to photovoltaic devices, such as solar cells, and, in particular, replaceable flexible, semi-rigid, or rigid solar modules for automotive use.

### Introduction

Photovoltaic devices, such as solar modules (cells or panels), harness energy from the sun to generate a voltage, thereby converting light energy to electric energy. Some vehicles include solar modules to charge a battery of the vehicle and/or provide electrical energy to one or more components of the vehicle. The solar modules are typically integrated onto surfaces of the vehicles.

During a lifetime of a vehicle, an integrated solar module may become damaged and need repaired as a result of, for example, wear-and-tear on the integrated solar module or impact damage due to a storm or crash. Solar modules integrated with glass panels are repaired by replacing the integrated glass panel. Similarly, solar-integrated hoods, bonnets, trunk lids, or other removable vehicle body parts are repaired by replacement of the entire solar integrated body part. However, solar-integrated fixed body panels (e.g., metal roofs or unibody panels) are not removable and thereby may not be repairable.

Accordingly, there exists a need for further improvements to solar-integrated vehicles.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an aspect, a removable photovoltaic panel for a vehicle is disclosed. The photovoltaic panel may include an array of photovoltaic devices interconnected and assembled together. The array of photovoltaic devices may include a form factor of a surface of a corresponding body panel of the vehicle. The photovoltaic panel may also include an attachment layer configured to attach the array of photovoltaic devices to the surface of the corresponding body panel.

In another aspect, a photovoltaic panel of a vehicle is disclosed. The photovoltaic panel may include a body panel of the vehicle. The photovoltaic panel may also include an array of photovoltaic devices interconnected and assembled together, the array of photovoltaic devices having a form factor of a surface of the body panel. The photovoltaic panel may also include an attachment layer configured to attach the array of photovoltaic devices to the surface of the body panel.

In another aspect, a method of removing and replacing a photovoltaic panel from a vehicle is disclosed. The method may include removing the photovoltaic panel from a body panel of the vehicle using one or more removal techniques. The method may also include applying an attachment layer to one or more of a second photovoltaic panel or a second body panel. The method may also include attaching the second photovoltaic panel to the second body panel.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is an example of a vehicle having a removable photovoltaic panel, according to aspects of the present disclosure;

FIG. 2 is an example of the removable photovoltaic panel of FIG. 1, according to aspects of the present disclosure;

FIG. 3 is an example of a photovoltaic device of the photovoltaic panel of FIG. 1, according to aspects of the present disclosure;

FIG. 4 is a flowchart of an example method of applying a photovoltaic panel to a vehicle, according to aspects of the present disclosure; and

FIG. 5 is a flowchart of an example method of removing and replacing a photovoltaic panel of a vehicle, according to aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Solar modules integrated into a vehicle are typically limited to removable vehicle parts, such as hoods, bonnets, trunk lids, and glass. Accordingly, while removable vehicle parts integrated with solar modules allow the vehicle to be repaired, full replacement of the removable vehicle parts integrated with the solar modules is required when the solar modules are damaged due to, for example, storms or crashes.

Further, vehicles containing fixed body parts, including panels for a roof, quarter panel, fender, pillar, etc, may provide additional surface areas for incorporation of solar modules. Use of the fixed body parts for solar modules may result in an increase in electrical energy generation of the vehicles due to the increase in surface area for use by the solar modules. The fixed body parts may also result in a significant increase in repair costs when solar modules are damaged. Typically, repair of fixed body parts is performed by pulling and smoothing dents, rather than removing and replacing panels, as these parts may be difficult to remove due to, for example, welded steel unibodies, which provide safer frames during a crash.

The present disclosure is directed towards removable flexible, semi-rigid, or rigid solar modules (or panels) and methods of attaching these solar modules to body parts (removable or fixed) of a vehicle such that the solar modules may be removed and replaced without removing and replacing the body parts on which the solar modules are attached to. In particular, the solar modules and methods described herein allow for simple and cost-effective removal and replacement of solar modules from a vehicle due to the structure of the solar modules and packaging schemes using one or more mounting techniques described herein. Implementation of the techniques and components described herein may allow laborers of a range of skill level to install, repair, and replace solar modules, and is not limited to highly skilled laborers located at, for example, vehicle dealerships.

Turning now to the figures, examples of photovoltaic devices and methods of manufacturing the photovoltaic devices are described herein. It is to be understood that layers and components in the figures may not be drawn to scale and are instead drawn for illustrative purposes.

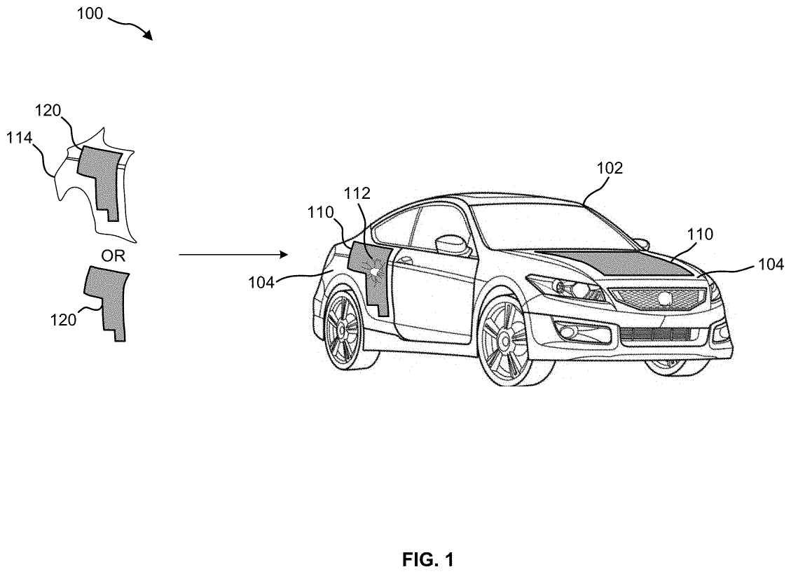

Referring to FIG. 1, an example 100 of a vehicle 102 having one or more flexible, semi-rigid, or rigid photovoltaic panels 110 is depicted. The vehicle 102 may be any type of vehicle 102, including, but not limited to, a car, truck, van, minivan, sport utility vehicle (SUV), motorcycle, scooter, boat, personal watercraft, aircraft, or any mechanically moving object that is capable of transporting one or more human occupants or other forms of cargo. The vehicle 102 may be formed of a plurality of body panels 104 (or body parts) that form an exterior surface of the vehicle 102. The body panels 104 may form flat or curved surfaces of the vehicle 102. The body panels 104 may be formed of one or more materials including, but not limited to, steel, aluminum, composites (e.g., fiberglass or carbon fiber), or plastics (e.g., filled or unfilled).

One or more of the photovoltaic panels (or module) 110 may mount to one or more of the plurality of body panels 104, as shown by FIG. 1.

In some situations, damage 112 may occur to one or more of the body panels 104 due to, for example, weather, a crash, or road debris. According to the present disclosure, the photovoltaic panel 110 having the damage 112 may be removed and replaced with a new photovoltaic panel 120. In some examples, the corresponding body panel 104 may be removed (e.g., to be repaired by pulling and smoothing dents), replaced with a second body panel 114 having a same form factor as the body panel 104 that is removed. In an example, the second body panel 114 may be the same body panel 104 after having been repaired or a new body panel.

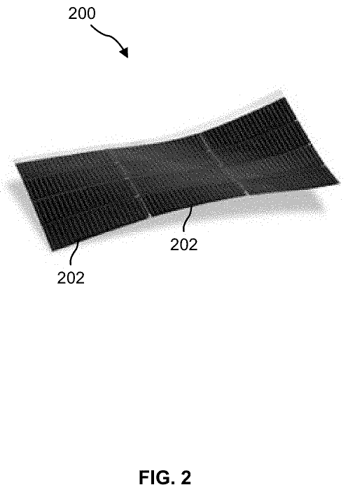

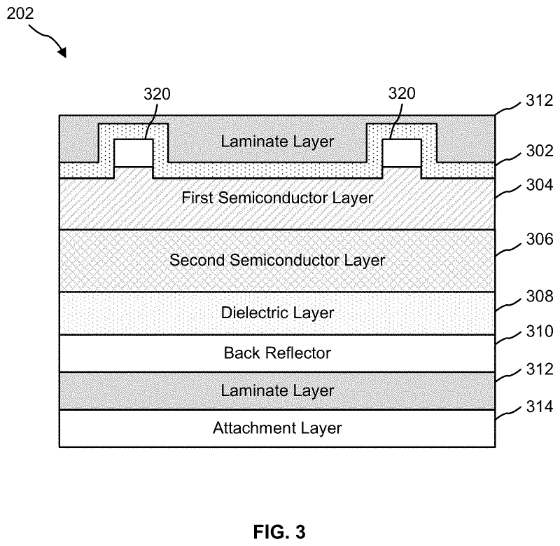

Referring to FIGS. 2 and 3, an example of a removable photovoltaic panel 200 is depicted. The removable photovoltaic panel 200 may be an example of the photovoltaic panels 110 or 120 of FIG. 1. In an aspect, the removable photovoltaic panel 200 may include an array of photovoltaic devices (e.g. solar cells) 202 that are interconnected and assembled together to aggregate current generated by each of the array of photovoltaic devices 202. In an example, the photovoltaic panel 200 may have a form factor according to a corresponding body panel 104.

An example of the photovoltaic device 202 may include a number of layers including one or more contact layers 320 located between an anti-reflective coating (ARC) layer 302 and a first semiconductor layer 304. The one or more contact layers 320 may conduct voltage and current, produced through a photovoltaic process, to external circuitry (not shown). In an aspect, the one or more contact layers 320 may include a metallic stack (e.g., metal contact stack) containing multiple layers of varying compositions of materials, as discussed herein.

In an example, the ARC layer 302 may be disposed on a front surface of a first semiconductor layer 304. In some examples, the ARC layer 302 may be deposited in removed or etched portions of the first semiconductor layer 304, as shown by FIG. 3. The ARC layer 302 may contain a material that allows light to pass through a front surface of the ARC layer 302 and prevent light reflection from the front surface of the ARC layer 302. In some examples, the ARC layer 302 may contain magnesium fluoride (MgF2), zinc sulfide (ZnS), titanium oxide (TiO), titanium dioxide (TiO2), niobium oxide (NbO, NbO2, or Nb2O5), silicon nitride (Si3N4), silicon oxynitride (SiOxNy), silicon oxide (SiO), silicon dioxide (SiO2), derivatives thereof, or combination thereof. In some examples, the ARC layer 302 may be one or more layers of material.

In some examples, the first semiconductor layer 304 may include compound semiconductor materials (e.g., non-silicon based materials) such as group III-V semiconductor materials, although other types of compound semiconductor materials may also be used (e.g., group II-IV semiconductor materials). The group III-V semiconductor material may include one or more group III semiconductor materials and one or more group V semiconductor materials (e.g., one group III semiconductor material and one group V semiconductor material, multiple group III semiconductor materials and one group V semiconductor material, one group III semiconductor material and multiple group V semiconductor materials, or multiple group III semiconductor materials and multiple group V semiconductor materials).

The group III-V semiconductor materials may include epitaxially grown layers which may contain a combination of two or more of gallium (Ga), arsenic (As), aluminum (Al), indium (In), or phosphorus (P) (e.g., GaAs, AlGaAs, InGaP, AlInGaP, InGaAs, AlInGaAs, InGaAsP, or AlInP). In some examples, the compound semiconductor materials of the first semiconductor layer 304 may include n-type (or n-doped) semiconductor materials or p-type (or p-doped) semiconductor materials. In some aspects, the first semiconductor layer 304 may also include a film stack containing multiple layers of varying compositions of materials including the group III-V semiconductor materials. For example, the first semiconductor layer 304 may include a contact layer, a front window, an absorber layer, and/or, an intermediate layer.

The photovoltaic device 202 may also include a second semiconductor layer 306. In some examples, the second semiconductor layer 306 may include compound semiconductor materials such as the group III-V semiconductor materials described above. The compound semiconductor materials of the second semiconductor layer 306 may include doped semiconductor materials opposite of the doped semiconductor materials of the first semiconductor layer 304. In some aspects, the compound semiconductor materials of the second semiconductor layer 306 may include a film stack containing multiple layers of varying compositions of materials including the group III-V semiconductor materials. For example, the second semiconductor layer 306 may include an emitter layer and/or a contact layer. During manufacturing, the second semiconductor layer 306 may be epitaxially grown on a back surface of the first semiconductor layer 304.

In an aspect, the photovoltaic device 202 may optionally include a dielectric layer 308. The dielectric layer 308 may boost the reflection or scattering of light impinging on or traveling through photovoltaic device 202. In some examples, the dielectric layer 308 may include an insulating material. In an example, the dielectric layer 308 may contact the second semiconductor layer 306. The dielectric layer 308 may be deposited on the back surface of the second semiconductor layer 306 during manufacturing.

The photovoltaic device 202 may also include a back reflector 310. The back reflector 310 may include a metal to reflect traversing light. Examples of metals may include gold (Au), silver (Ag), copper (Cu), aluminum (Al), or other reflective metals, derivatives thereof, and/or combinations thereof. The back reflector 310 may contact a surface of the dielectric layer 308. In some examples, the back reflector 310 may be deposited on the back surface of the dielectric layer 308 during manufacturing. The dielectric layer 308 and/or the back reflector 310 may be textured in order to improve the overall efficiency of the photovoltaic device 202.

The photovoltaic device 202 may also include a laminate layer 312 configured to surround the photovoltaic device 202 and/or the photovoltaic panel 200. In an example, the laminate layer 312 may form a protective layer over the photovoltaic device 202 and/or the photovoltaic panel 200 to prevent debris from contacting any of the photovoltaic devices 202. The laminate layer 312 may be formed of plastic, flexible glass, or any laminate material having a high light transmission rate (e.g., greater than 80%).

The photovoltaic device 202 may also include an attachment layer 314 configured to attach the photovoltaic device 202 (and/or the photovoltaic panel 200) to a corresponding body panel 104 of the vehicle 102. In an example, and as shown by FIG. 2, the attachment layer 314 may attach to a back surface of the photovoltaic device 202 (and/or the photovoltaic panel 200).

In an aspect, the attachment layer 314 may be formed of a material having unique bonding requirements and specific solutions for a corresponding body panel 104 of the vehicle 102. In an aspect, the attachment layer 314 may include a material having a bond strength that can withstand high wind shear forces, an ability to seal to a surface of the corresponding body panel 104 and prevent or minimize moisture intrusion (or allow trapped moisture to be release) behind photovoltaic device 202, a bond strength that can handle extreme vehicle surface temperatures (e.g., greater than 100 degrees Celsius or less than −40 degrees Celsius), and a simple methodology for removal and a replacement of the photovoltaic device 202 (and/or the photovoltaic panel 200) from the corresponding body panel 104.

In an aspect, the attachment layer 314 may be deposited on the photovoltaic device 202 during manufacturing of the photovoltaic device 202 or after assembly of the photovoltaic panel 200, or the attachment layer 314 may be deposited on a corresponding body panel 104 and the photovoltaic device 202 or the photovoltaic panel 200 may be attached to the attachment layer 314 deposited on the vehicle 102.

In an example, the attachment layer 314 may include a material having a suitably bondable packaging back sheet and an adhesive compound that can be thermally released from a surface of the corresponding body panel 104 and/or released from a surface (e.g., laminate layer 312) of the photovoltaic device 202. In some examples, an adhesive of the attachment layer 314 may release by application of direct heat to melt or otherwise weaken a bond strength of the adhesive. Examples of this adhesive may include, but is not limited to, pressure sensitive adhesives (PSAs), thermoplastic adhesives, thermoset adhesives, or curable resins.

In some examples, the attachment layer 314 may include a material having an adhesive that can be released from a surface of the corresponding body panel 104 and/or released from a surface (e.g., laminate layer 312) of the photovoltaic device 202 by utilizing a light-to-heat-conversion to weaken the bond strength. Examples, of this adhesive may include, but are not limited to, 3M's Wafer Support System adhesive. In this example, a device, such as a laser may be used to weaken the bond strength.

In some examples, the attachment layer 314 may include a material having an adhesive that can be released from a surface of the corresponding body panel 104 and/or released from a surface (e.g., laminate layer 312) of the photovoltaic device 202 by electromagnetic excitation. Examples of this type of adhesive may include components, structures, or additives that can be inductively heated via electromagnetic excitation.

In some examples, the attachment layer 314 may include a material having a suitably bondable packaging back sheet and an adhesive compound that can be embrittled or otherwise photochemically altered to weaken bond strength via ultraviolet (UV) or other electromagnetic radiation exposure.

In some examples, the attachment layer 314 may include a material having a magnetic back sheet to bond to, for example, a surface of a corresponding body panel 104 formed of steel or other metallic surface.

In some examples, the attachment layer 314 may include a material formed of a mechanical interlock/fasteners that can be released with tooling or via a simple component removal that allows access. Examples of the mechanical interlock/fasteners may include, but are not limited to, hook-&-loop material (e.g., Velcro), mechanical interlocks (e.g., 3M Dual Lock), or sliding interlocks.

In some examples, the attachment layer 314 may include a material having a suitably bondable packaging back sheet and an adhesive compound that weakens a bond strength by deformable release, such as stretching the attachment layer 314 to cause the bond to weaken.

While the photovoltaic device 202 is depicted having the attachment layer 314, not every photovoltaic device 202 of the photovoltaic panel 200 may include the attachment layer 314. For example, mechanical interlock/fasteners may contact some of the plurality of photovoltaic devices 202.

Further, while the above-described example of the photovoltaic device 202 is described to include one or more contact layers 320, the ARC layer 302, the first semiconductor layer 304, the second semiconductor layer 306, the dielectric layer 308, the back reflector 310, the laminate layer 312, and the attachment layer 314, in other examples, the photovoltaic device 202 may include one or more additional layers or exclude one or more of the described layers according to the application of the photovoltaic device 202 with a vehicle 102. For example, applications, the layers of the photovoltaic device 202 may include layers corresponding to a crystalline silicon (c-Si) solar cell, a copper indium gallium selenide (CIGS) solar cell, a perovskite solar cell (PSC), and/or include other photovoltaic materials that can be deformed and still produce power.

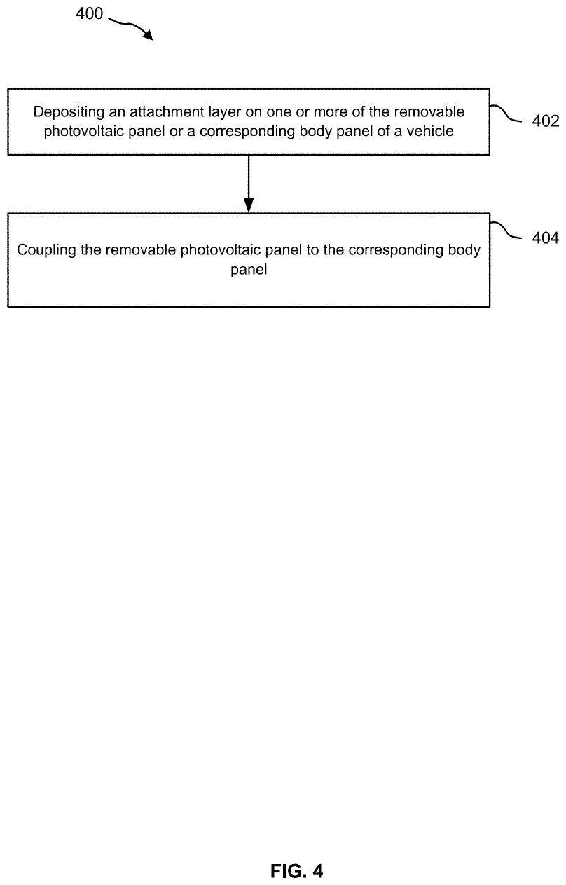

Referring to FIG. 4, an example of a method 400 for applying the removable photovoltaic panel 200 to the vehicle 102, according to aspects of the present disclosure, is depicted. At 402, the method 400 may include depositing an attachment layer on one or more of the removable photovoltaic panel or a corresponding body panel of a vehicle. For example, one or more materials described herein for the attachment layer 314 may be applied to the back surface of the photovoltaic device 202 (or the photovoltaic panel 200) or the surface of the corresponding body panel 104.

At 404, the method 400 may include coupling the removable photovoltaic panel to the corresponding body panel. For example, the removable photovoltaic panel 200 may be coupled with the surface of the corresponding body panel 104 through pressure, mechanically connection, hooks, or any other technique or devices described herein.

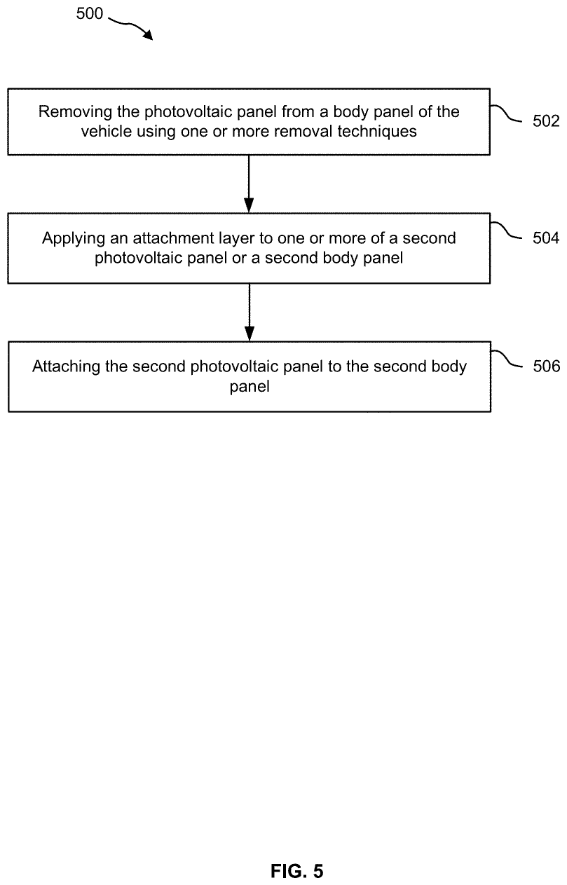

Referring to FIG. 5, an example of a method 500 for removing and replacing the removable photovoltaic panel 200 from the vehicle 102, according to aspects of the present disclosure, is depicted. At 502, the method 500 may include removing the photovoltaic panel from a body panel of the vehicle using one or more removal techniques. For example, the photovoltaic panel 110 with the damage 112 may be removed from the corresponding body panel 104. In an example, the removable photovoltaic panel 110 may be removed from the body panel 104 through one or more of thermal release, light-to-heat release, electromagnetic excitation release, photochemical release, magnetic release, mechanical release, or deformable release, as described herein.

At 504, the method 500 may include applying an attachment layer to one or more of a second photovoltaic panel or a second body panel. For example, the attachment layer 314 may be applied to one or more of a second photovoltaic panel 120 or a second body panel (e.g., 110 or 114), as described herein.

At 506, the method 500 may include attaching the second photovoltaic panel to the second body panel. For example, the second photovoltaic panel 120 may be applied to the second body panel (e.g., 110 or 114), as described by the method 400.

In some examples, the method 500 may optionally include removing the body panel from the vehicle. For example, the body panel 104 may be removed from the vehicle 102.

In some examples, the method 500 may include installing the second body panel on the vehicle, wherein the body panel is different from the second body panel. For example, the body panel 114 may be the same body panel 104 after having been repaired or a new body panel.

It is understood that the specific order or hierarchy of blocks in the processes/flowcharts disclosed is an illustration of exemplary approaches. Based upon different implementations, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more.

Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. A removable photovoltaic panel for a vehicle, comprising:
an array of photovoltaic devices interconnected and assembled together, the array of photovoltaic devices having a form factor of a surface of a corresponding body panel of the vehicle; and
an attachment layer configured to attach the array of photovoltaic devices to the surface of the corresponding body panel.

2. The removable photovoltaic panel of claim 1, wherein the attachment layer is coupled with a back surface of one or more photovoltaic devices of the array of photovoltaic devices and the surface of the corresponding body panel.

3. The removable photovoltaic panel of claim 1, wherein the attachment layer is deposited on one or more photovoltaic devices of the array of photovoltaic devices.

4. The removable photovoltaic panel of claim 1, wherein the attachment layer is formed of a material having a bonding requirement unique for the surface of the corresponding body panel.

5. The removable photovoltaic panel of claim 1, wherein the attachment layer is configured to form a seal with the surface of the corresponding body panel.

6. The removable photovoltaic panel of claim 1, wherein the attachment layer is formed of a material having an adhesive compound configured for thermal release from the surface of the corresponding body panel.

7. The removable photovoltaic panel of claim 6, wherein the adhesive compound is one or more of pressure sensitive adhesives (PSAs), thermoplastic adhesives, thermoset adhesives, or curable resins.

8. The removable photovoltaic panel of claim 1, wherein the attachment layer is formed of a material having an adhesive compound configured for light-to-heat release from the surface of the corresponding body panel.

9. The removable photovoltaic panel of claim 1, wherein the attachment layer is formed of a material having an adhesive compound configured for electromagnetic excitation release from the surface of the corresponding body panel.

10. The removable photovoltaic panel of claim 1, wherein the attachment layer is formed of a material having an adhesive compound configured for photochemical release from the surface of the corresponding body panel.

11. The removable photovoltaic panel of claim 10, wherein the photochemical release includes ultraviolet (UV) release.

12. The removable photovoltaic panel of claim 1, wherein the attachment layer is formed of a material having an adhesive compound configured for of magnetic release from the surface of the corresponding body panel.

13. The removable photovoltaic panel of claim 1, wherein the attachment layer is formed of a material configured for a mechanical release from the surface of the corresponding body panel.

14. The removable photovoltaic panel of claim 13, wherein the mechanical release includes one or more of a hook-and-loop material, a mechanical interlock, or a sliding interlock.

15. The removable photovoltaic panel of claim 1, wherein the attachment layer is formed of a material for deformable release from the surface of the corresponding body panel.

16. A photovoltaic panel of a vehicle, comprising:
a body panel of the vehicle;
an array of photovoltaic devices interconnected and assembled together, the array of photovoltaic devices having a form factor of a surface of the body panel; and
an attachment layer configured to attach the array of photovoltaic devices to the surface of the body panel.

17. The photovoltaic panel of claim 16, wherein the attachment layer is formed of a material having a bonding requirement unique for the surface of the body panel.

18. The photovoltaic panel of claim 16, wherein the attachment layer is configured to form a seal with the surface of the body panel.

19. The photovoltaic panel of claim 16, wherein the attachment layer is formed of a material having an adhesive compound configured for thermal release from the surface of the body panel.

20. The photovoltaic panel of claim 19, wherein the adhesive compound is one or more of pressure sensitive adhesives (PSAs), thermoplastic adhesives, thermoset adhesives, or curable resins.
